(19) United States
(12) Patent Application Publication
(10) Pub. No.: US 2020/0028328 A1
(43) Pub. Date: Jan. 23, 2020

(54) VERTICAL CAVITY SURFACE EMITTING LASER

(71) Applicant: Sumitomo Electric Industries, LTD., Osaka (JP)

(72) Inventors: Suguru ARIKATA, Oaska (JP); Susumu YOSHIMOTO, Osaka (JP); Takamichi SUMITOMO, Osaka (JP); Kei FUJII, Osaka (JP)

(73) Assignee: Sumitomo Electric Industries, LTD., Osaka (JP)

(21) Appl. No.: 16/515,202

(22) Filed: Jul. 18, 2019

(30) Foreign Application Priority Data
Jul. 23, 2018 (JP) 2018-137901

(51) Int. Cl. H01S 5/183; H01S 5/187; H01S 5/34; H01S 5/343

(52) U.S. Cl. CPC H01S 5/18361; H01S 5/34346; H01S 5/341; H01S 5/187

(57) ABSTRACT

A vertical cavity surface emitting laser includes an active layer having a quantum well structure, a first laminate for a first distributed Bragg reflector, and a first spacer region provided between the active layer and the first laminate. A barrier layer of the quantum well structure includes a first compound semiconductor containing aluminum as a group m constituent element. The first spacer region includes a second compound semiconductor having a larger aluminum composition than the first compound semiconductor. A concentration of first dopant in the first laminate is larger than a concentration of the first dopant in the first portion of the first spacer region. The concentration of the first dopant in the first portion of the first spacer region is larger than a concentration of the first dopant in the second portion of the first spacer region.

### CROSS REFERENCE TO RELATED APPLICATIONS

The present application is based upon and claims the benefit of the priority from Japanese patent application No. 2018-137901, filed on Jul. 23, 2018, which is hereby incorporated by reference in its entirety.

### TECHNICAL FIELD

The present disclosure relates to a vertical cavity surface emitting laser and a method for producing the vertical cavity surface emitting laser.

### BACKGROUND

Japanese Patent Application Laid-Open No. 2007-142375 discloses a vertical cavity surface emitting laser.

### SUMMARY

The present disclosure provides a vertical cavity surface emitting laser. The vertical cavity surface emitting laser includes an active layer having a quantum well structure including a well layer and a barrier layer, a first laminate for a first distributed Bragg reflector, and a first spacer region provided between the active layer and the first laminate. The barrier layer includes a first compound semiconductor containing aluminum as a group H constituent element; the first spacer region includes a second compound semiconductor having a larger aluminum composition than the first compound semiconductor; the first spacer region includes a first portion and a second portion; the first laminate, the first portion of the first spacer region, the second portion of the first spacer region, and the active layer are arranged along a direction of a first axis; the first portion of the first spacer region and the first laminate contain first dopant; the first portion of the first spacer region is provided from the first laminate to the second portion of the first spacer region; the second portion of the first spacer region is provided from the active layer to the first portion of the first spacer region; a concentration of the first dopant in the first laminate is larger than a concentration of the first dopant in the first portion of the first spacer region; and the concentration of the first dopant in the first portion of the first spacer region is larger than a concentration of the first dopant in the second portion of the first spacer region.

### BRIEF DESCRIPTION OF THE DRAWINGS

The foregoing and other purposes, aspects and advantages will be better understood from the following detailed description of a preferred embodiment of the invention with reference to the drawings, in which:

FIG. 1 is a partially cutaway view schematically illustrating a vertical cavity surface emitting laser according to the present embodiment;

FIG. 2 is a view schematically illustrating a main step in a method for producing the vertical cavity surface emitting laser according to the present embodiment;

FIG. 3 is a view schematically illustrating a main step in a method for producing the vertical cavity surface emitting laser according to the present embodiment;

FIG. 4 is a view schematically illustrating a main step in a method for producing the vertical cavity surface emitting laser according to the present embodiment;

FIG. 5 is a view schematically illustrating a main step in a method for producing the vertical cavity surface emitting laser according to the present embodiment;

FIG. 6 is a view schematically illustrating a main step in a method for producing the vertical cavity surface emitting laser according to the present embodiment; and

FIG. 7 is a view illustrating three dopant profiles in a first laminate, a spacer region having mutually different aluminum compositions, and an active layer in a vertical cavity surface emitting laser according to an example.

### DETAILED DESCRIPTION

### Problem to be Solved by the Present Disclosure

In application fields of a vertical cavity surface emitting laser, such as optical communication, there is a demand for a high-speed modulation and a low threshold value in the vertical resonant type surface emitting laser. According to findings of the inventor, some vertical cavity surface emitting lasers exhibit variation in the emission intensity over time. It is desirable to reduce the variation over time in the emission intensity.

### Advantageous Effect of the Present Disclosure

According to the present disclosure, a vertical cavity surface emitting laser that makes it possible to reduce the variation over time in its emission characteristics is provided.

### DESCRIPTION OF EMBODIMENTS OF THE PRESENT DISCLOSURE

Some specific examples will be described.

A vertical cavity surface emitting laser according to a specific example includes (a) an active layer having a quantum well structure including a well layer and a barrier layer, (b) a first laminate for a first distributed Bragg reflector, and (c) a spacer region provided between the active layer and the first laminate. The barrier layer includes a first compound semiconductor containing aluminum as a group III constituent element; the first spacer region includes a second compound semiconductor having a larger aluminum composition than the first compound semiconductor; the first spacer region includes a first portion and a second portion; the first laminate, the first portion of the first spacer region, the second portion of the first spacer region, and the active layer are arranged along a direction of a first axis; the first portion of the first spacer region and the first laminate contain first dopant; the first portion of the first spacer region is provided from the first laminate to the second portion of the first spacer region; the second portion of the first spacer region is provided from the active layer to the first portion of the first spacer region; the concentration of the first dopant in the first laminate is larger than the concentration of the first dopant in the first portion of the first spacer region; and the concentration of the first dopant in the first portion of the first spacer region is larger than the concentration of the first dopant in the second portion of the first spacer region.

According to the vertical cavity surface emitting laser, the first spacer, which is provided between the active layer and the first laminate, includes the first portion and the second portion. The first portion and the second portion include a compound semiconductor containing aluminum as a group m constituent element, and this compound semiconductor has a larger aluminum composition than an aluminum composition of the barrier layer of the active layer. The first laminate is in contact with the first portion of the first spacer region, and the active layer is in contact with the second portion of the first spacer region.

Specifically, the first spacer region, which provides the first portion with the large aluminum composition, enables the amount of dopant that approaches from the first laminate to the first portion of the first spacer region by diffusion to be reduced by a heat treatment during a production. According to the first spacer region, which provides the second portion with the large aluminum composition, a structure that, by diffusion during the production, makes it hard for the dopant to reach the active layer from the first laminate can be provided. In the first spacer region, the dopant concentration in the second portion is smaller than the dopant concentration in the first portion.

The dopant concentration in the active layer can be made very low, for example, smaller than a detection lower limit. According to the low dopant concentration of the second portion, the generations of non-radiative recombination centers due to diffused dopant are highly unlikely to occur in the active layer. Further, the doped first portion in a path from the first laminate to the second portion of the first spacer region (the first portion having a dopant concentration larger than the dopant concentration of the second portion of the first spacer region and smaller than the dopant concentration of the first laminate) can be provided to a carrier path from the first laminate to the active layer.

In a vertical cavity surface emitting laser according to a specific example, the second compound semiconductor has an aluminum composition larger than or equal to 0.35; the first laminate contains n-type dopant larger than or equal to 1×10¹⁸ cm⁻³; and the distance between the active layer and the first laminate is larger than or equal to 10 nanometers in the direction of the first axis.

According to the vertical cavity surface emitting laser, the first spacer region separates, from the active layer, the first laminate having such a high n-type dopant concentration larger than or equal to 1×10¹⁸ cm⁻³. In the production of the vertical cavity surface emitting laser, after semiconductor layers for the first laminate have been grown, a semiconductor region located upper than the first laminate is grown. The semiconductor layers for the first laminate receive heat when, after the growths thereof, the semiconductor region is grown above the first laminate. The total amount of this heat energy depends on, not the layer structure of the first laminate, but the total thickness of semiconductor layers located upper than the first laminate. According to the first spacer region including the first portion and the second portion that have mutually different n-type dopant concentrations, it is blocked that the dopant reaches the active layer from the first laminate by being diffused thereinto from the region larger than or equal to 1×10¹⁸ cm⁻³ during the production. As a result, the dopant concentration in the active layer can be made very low, for example, smaller than a detection lower limit.

In a vertical cavity surface emitting laser according to a specific example, the concentration of the above first dopant in the first portion of the first spacer region is larger than or equal to 1×10¹⁷ cm⁻³, and the concentration of the first dopant in the second portion of the first spacer region is smaller than 1×10¹⁷ cm⁻³.

According to the vertical cavity surface emitting laser, the first portion having the first dopant concentration larger than or equal to 1×10¹⁷ cm⁻³ and the second portion having the first dopant concentration smaller than 1×10¹⁷ cm⁻³ have a dopant profile that monotonically changes in a direction from the first laminate to the active layer.

In a vertical cavity surface emitting laser according to a specific example, the concentration of the first dopant in the active layer is smaller than 1×10¹⁶ cm³, and the quantum well structure contains Al_{X}Ga_{1-X}As/In_{1-V}Ga_{Y}As, here, 0.05≤Y≤0.5 being satisfied.

According to the vertical cavity surface emitting laser, in the quantum well structure, the generations of non-radiative recombination centers due to the dopant diffusion are reduced.

In a vertical cavity surface emitting laser according to a specific example, the concentration of the first dopant in the active layer is smaller than 1×10¹⁶ cm³, and the quantum well structure contains Al_{X}Ga_{1-X}As/In_{U}Al_{V}Ga_{1-U-V}As, here, 0.05≤U≤0.5 and 0<V≤0.2 being satisfied.

According to the vertical cavity surface emitting laser, in the quantum well structure, the generations of non-radiative recombination centers due to the dopant diffusion are reduced.

A vertical cavity surface emitting laser according to a specific example includes a substrate, a second laminate for a second distributed Bragg reflector, and a second spacer region provided between the active layer and the second laminate. The first spacer region and the first laminate are provided between the substrate and the active layer; the active layer is provided between the first laminate and the second laminate; and the second laminate, a first portion of the second spacer region, a second portion of the second spacer region, and the active layer are arranged along the direction of the first axis.

According to the vertical cavity surface emitting laser, the first spacer region and the first laminate are provided between the substrate and the active layer, and in the film forming of the relevant vertical cavity surface emitting laser, after the growths of the first spacer region and the first laminate, the first spacer region and the first laminate are exposed to a high temperature during a period of the growth of the upper region including the second spacer region and the second laminate.

### DETAILED DESCRIPTION OF THE EMBODIMENTS OF THE PRESENT DISCLOSURE

The findings of the present disclosure can be easily understood by considering the following detailed description with reference to the accompanying drawings that are shown as exemplification. Subsequently, an embodiment associated with a vertical cavity surface emitting laser and a method for producing the vertical cavity surface emitting laser will be described with reference to the accompanying drawings. In possible cases, the same signs are given to the same portions.

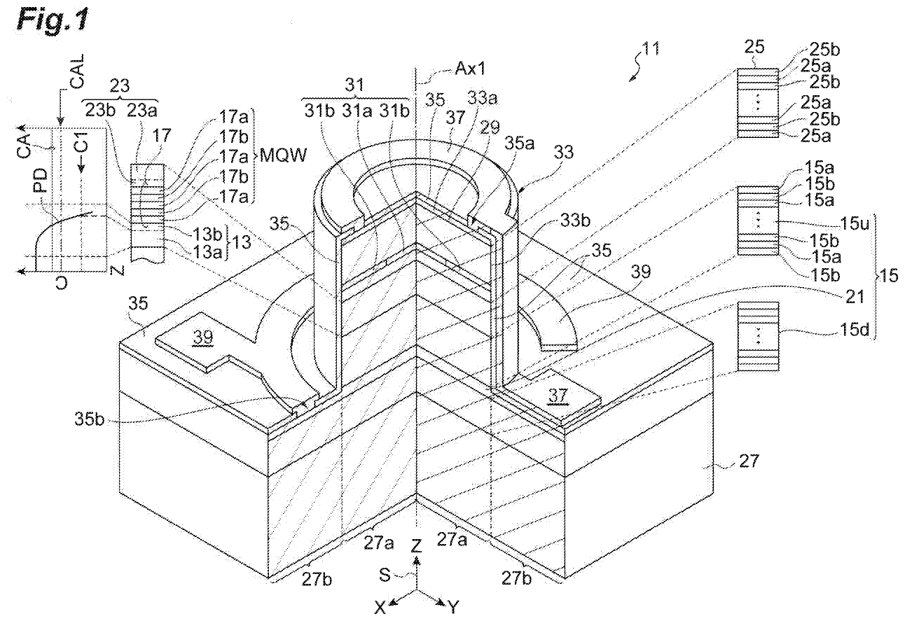

FIG. 1 is a partially cutaway view schematically illustrating a vertical cavity surface emitting laser according to the present embodiment. In FIG. 1, an orthogonal coordinate system S is illustrated, and a Z-axis is directed in the direction of a first axis Ax1. A vertical cavity surface emitting laser 11 includes a first spacer region 13, a first laminate 15, and an active layer 17. The first spacer region 13 is provided between the first laminate 15 and the active layer 17.

The first spacer region 13 includes a first portion 13a and a second portion 13b. The first laminate 15, the first portion 13a of the first spacer region 13, the second portion 13b of the first spacer region 13, and the active layer 17 are arranged along the direction of the first axis Ax1. In the first spacer region 13, the first portion 13a extends from the first laminate 15 to the second portion 13b, and the second portion 13b extends from the active layer 17 to the first portion 13a.

The active layer 17 includes a quantum well structure MQW, and the quantum well structure MQW includes a plurality of well layers 17a and one or more barrier layers 17b. The well layers 17a and the one or more barrier layers 17b are alternately arranged in the direction of the first axis Ax1.

Each of the well layer 17a and the barrier layer 17b includes a compound semiconductor containing group II and group V constituent elements. The first spacer region 13 includes a compound semiconductor having a larger aluminum composition than the compound semiconductor of the barrier layer 17b.

The first portion 13a of the first spacer region 13 contains first dopant, and the first laminate 15 contains the first dopant. The dopant can give electrical conductivity to a semiconductor. The concentration of the first dopant in the first laminate 15 is larger than the concentration of the first dopant in the first portion 13a of the first spacer region 13, and the concentration of the first dopant in the first portion 13a of the first spacer region 13 is larger than the concentration of the first dopant in the second portion 13b of the first spacer region 13.

The first laminate 15 is provided for a first distributed Bragg reflector, and specifically, includes first semiconductor layers 15a and second semiconductor layers 15b, the first semiconductor layers 15a and the second semiconductor layers 15b being alternately arranged in such a way as to constitute the first distributed Bragg reflector.

According to the vertical cavity surface emitting laser 11, the first spacer region 13 provided between the first laminate 15 and the active layer 17 includes the first portion 13a and the second portion 13b. The first portion 13a and the second portion 13b include a compound semiconductor containing aluminum as a group III constituent element, and this compound semiconductor has an aluminum composition larger than the aluminum composition of the barrier layer 17b of the active layer 17. In the first spacer region 13, the first portion 13a reaches the second portion 13b from the first laminate 15. The second portion 13b reaches the first portion 13a from the active layer 17.

Specifically, the first spacer region 13, which provides the first portion 13a with a large aluminum composition, enables the amount of dopant that reaches the first portion 13a of the first spacer region 13 from the first laminate 15 by diffusion to be reduced by a heat treatment during a production. According to the first spacer region 13, which provides the second portion 13b with a large aluminum composition, a structure that, through diffusion during a production, makes it hard for the dopant to reach the active layer 17 from the first laminate 15 can be provided. In the first spacer region 13, the dopant concentration in the second portion 13b is smaller than the dopant concentration in the first portion 13a.

The dopant in the active layer 17 can be made very low, for example, smaller than a detection lower limit. According to the low dopant concentration of the second portion 13b, the generations of non-radiative recombination centers due to diffused dopant are highly unlikely to occur in the active layer 17. Further, the doped first portion 13a in a path from the first laminate 15 to the second portion 13b of the first spacer region 13 (the first portion 13a having a dopant concentration larger than the dopant concentration of the second portion 13b of the first spacer region 13 and smaller than the dopant concentration of the first laminate 15) can be provided to a carrier path from the first laminate 15 to the active layer 17.

The first laminate 15 can contain, for example, n-type dopant, and the concentration of the n-type dopant can be larger than or equal to, for example, 1×10¹⁸ cm⁻³. The n-type dopant of the first laminate 15 can be smaller or equal to, for example, 1×10¹⁹ cm⁻³. According to the vertical cavity surface emitting laser 11, the first spacer region 13 separates, from the active layer 17, the first laminate 15 having such a high n-type dopant concentration larger than or equal to 1×10¹⁸ cm⁻³.

In the production of the vertical cavity surface emitting laser 11, after semiconductor layers for the first laminate 15 are grown, a semiconductor region located upper than the first laminate 15 is grown. The semiconductors of the first laminate 15 receive heat when, after the growth thereof, the semiconductor region is grown above the first laminate 15. The total amount of this heat energy depends on, not the layer structure of the first laminate 15, but the total thickness of a layer structure located upper than the first laminate 15. According to the first spacer region 13 including the first portion 13a and the second portion 13b that have mutually different n-type dopant concentrations, it is blocked that, because of the dopant diffusion during the production, the dopant reaches the active layer 17 from the first laminate 15 in which the dominant is larger than or equal to 1×10¹⁸ cm⁻³. As a result, the dopant in the active layer 17 can be made very low, for example, smaller than a detection lower limit. According to the low dopant concentration of the second portion 13b, any generation of a non-radiative recombination center due to the diffused dopant does not substantially occur in the active layer 17.

According to the vertical cavity surface emitting laser 11, the first dopant concentration is represented by a dopant profile (for example, a dopant profile PD illustrated in FIG. 1) having a portion that monotonically changes in a direction from the first laminate 15 to the active layer 17, in the first portion 13a and the second portion 13b of the first spacer region 13 from the first laminate 15 having a high dopant.

The vertical cavity surface emitting laser 11 further includes a lower contact layer 21. In the present example, the first laminate 15 includes the lower contact layer 21. In the present example, the first laminate 15 includes an upper laminate portion 15u and a lower laminate portion 15d, and the lower contact layer 21 is directed between the upper laminate portion 15u and the lower laminate portion 15d. Each of the upper laminate portion 15u and the lower laminate portion 15d of the first laminate 15 is provided for the first distributed Bragg reflector, and includes the first semiconductor layers 15a and the second semiconductor layers 15b, the first semiconductor layers 15a and the second semiconductor layers 15b being alternately arranged in such a way as to constitute the first distributed Bragg reflector.

The first portion 13a of the first spacer region 13 has a dopant concentration larger than or equal to, for example, 1×10¹⁷ cm⁻³, and the second portion 13b has a first dopant concentration smaller than, for example, 1×10¹⁷ cm⁻³. In FIG. 1, a sign “C1” denotes a dopant level of, for example, 1×10¹⁷ cm⁻³. In the first spacer region 13 having a substantially single composition, the dopant profile PD has a monotonously decreasing portion in the first spacer region 13.

Specifically, for example, in the first portion 13a of the first spacer region 13, the dopant concentration represented by the dopant profile PD monotonously decreases from a value at the boundary between the first laminate 15 and the first spacer region 13, and sometimes reaches a dopant concentration smaller than 1×10¹⁷ cm⁻³ at the boundary between the first portion 13a and the second portion 13b. The first portion 13a and the second portion 13b may be configured to have, for example, the same thickness.

A semiconductor (for example, AlGaAs) having a high aluminum composition (an aluminum composition larger than, for example, 0.50) brings about the occurrence of oxidization, a high bandgap, and a high specific resistance on a semiconductor device.

From these viewpoints, spacer regions (13 and 23) are preferable to have an aluminum composition larger than or equal to 0.30 and smaller than or equal to 0.50.

In the present example, the distance between the first laminate 15 and the active layer 17 is larger than or equal to 5 nanometers in the direction of the first axis Ax1, and the first spacer region 13 fills in a gap between the first laminate 15 and the active layer 17. When the distance is too small, it is difficult to decrease the concentrations for non-radiative recombination centers of the active layer. When the distance is too small, the emission intensity of the device is affected.

The distance between the first laminate 15 and the active layer 17 is smaller than or equal to 20 nanometers in the direction of the first axis Ax1, and the first spacer region 13 fills in a gap between the first laminate 15 and the active layer 17. When the distance is too large, the electrical conductivity between the lower contact layer and the active layer is decreased (the resistance is increased), and it becomes difficult to achieve a high-speed modulation. The upper limit of the distance enables the electrical conductivity to be sufficiently ensured.

Further, the first portion 13a in a path from the first laminate 15 to the second portion 13b of the first spacer region 13 (the first portion 13a having a dopant concentration larger than 1×10¹⁶ cm⁻³) is provided to carriers flowing from the first laminate 15 to the active layer 17. In the vertical cavity surface emitting laser 11 including a thick laminate that implements two distributed Bragg reflectors, the first spacer region 13, which includes the first portion 13a and the second portion 13b that are located between the lower contact layer 21 and the active layer 17, can prevent that the dopant distribution in the vicinity of the active layer 17 restricts a high-speed modulation performance.

According to the vertical cavity surface emitting laser 11, at least a portion of the first portion 13a having the first dopant concentration larger than or equal to 1×10¹⁷ cm⁻³ and at least a portion of the second portion 13b having the first dopant concentration smaller than 1×10¹⁷ cm³ has a dopant profile that monotonously changes in the direction from the first laminate 15 to the active layer 17. The monotonously decreasing dopant profile in the spacer region makes a low dopant concentration possible in a portion near the active layer, and makes a high dopant concentration possible in a portion far from the active layer, thereby enabling a low resistance to be provided to the spacer region.

The first dopant includes, for example, silicon (Si), sulfur (S), and tellurium (Te). Alternatively, the first dopant can include, for example, zinc (Zn), beryllium (Be), magnesium (Mg), and carbon (C).

The quantum well structure MQW of the active layer 17 can contain, for example, GaAs/AlGaAs, Al_{X}Ga_{1-X}As/In_{1-Y}Ga_{Y}As, and/or Al_{X}Ga_{1-X}As/In_{U}Al_{V}Ga_{1-U-V}As. According to the vertical cavity surface emitting laser 11, in the quantum well structure MQW, the generations of non-radiative recombination centers due to the dopant diffusion are reduced.

In the quantum well structure MQW containing Al_{X}Ga_{1-X}As/GaAs, specifically, the following relation is satisfied: 0.2≤X≤0.5. This range for X allows the emission efficiency of the quantum well to be sufficient.

In the quantum well structure MQW containing Al_{X}Ga_{1-X}As/In_{1-Y}Ga_{Y}As, specifically, the following relations are satisfied: 0.2≤X≤0.5 and 0.05≤Y≤0.5. This range of X allows the emission efficiency of the quantum well to be sufficient.

Further, in the quantum well structure MQW containing Al_{X}Ga_{1-X}As/In_{U}Al_{V}Ga_{1-U-V}As, specifically, the following relations are satisfied: 0.05≤U≤0.5, 0<V≤0.2, and 0.2≤X≤0.5. The ranges (U and V) for Al and In of the well layer are for obtaining a desired oscillation wavelength.

In the quantum well structure MQW having these compositions, the concentration of the first dopant is smaller than 1<10¹⁶ cm⁻³, and the generations of non-radiative recombination centers due to the diffused dopant are reduced in the active layer 17.

The vertical cavity surface emitting laser 11 further includes a second spacer region 23 and a second laminate 25. The second laminate 25 is provided for a second distributed Bragg reflector, and specifically, includes first semiconductor layers 25a and second semiconductor layers 25b, the first semiconductor layers 25a and the second semiconductor layers 25b being alternately arranged in such a way as to constitute the second distributed Bragg reflector. The second spacer region 23 is provided between the active layer 17 and the second laminate 25. The second laminate 25, the second spacer region 23, and the active layer 17 are arranged along the direction of the first axis Ax1. The active layer 17 is provided between the first spacer region 13 and the second spacer region 23. The second laminate 25 contains second dopant having a conductivity type reverse to that of the first dopant, and the dopant can give electrical conductivity to a semiconductor. The second spacer region 23 can contain the second dopant.

The second laminate 25 can contain, for example, p-type dopant, and the p-type dopant concentration can be larger than or equal to, for example, 1×10¹⁸ cm⁻³. The p-type dopant concentration of the second laminate 25 can be smaller or equal to, for example, 1×10¹⁹ cm⁻³. According to the vertical cavity surface emitting laser 11, the second spacer region 23 separates, from the active layer 17, the second laminate 25 having such a high p-type dopant concentration larger than or equal to 1×10¹⁸ cm⁻³.

The vertical cavity surface emitting laser 11 can include a second laminate 25 containing the n-type dopant instead of the second laminate 25 containing the p-type dopant, and this vertical cavity surface emitting laser 11 includes a first laminate 15 containing the p-type dopant instead of the first laminate 15 containing the n-type dopant.

In possible cases, the second spacer region 23 includes a first portion 23a and a second portion 23b, and the first portion 23a and the second portion 23b are provided between the second laminate 25 and the active layer 17. More specifically, the second laminate 25, the first portion 23a of the second spacer region 23, the second portion 23b of the second spacer region 23, and the active layer 17 are arranged along the direction of the first axis Ax1. In the second spacer region 23, the first portion 23a is provided in such a way as to reach the second portion 23b from the second laminate 25, and the second portion 23b is provided in such a way as to reach the first portion 23a from the active layer 17. In the second spacer region 23, the dopant concentration in the second portion 23b is smaller than the dopant concentration in the first portion 23a, and the concentration of the second dopant is smaller than 1×10¹⁶ cm³ in the active layer 17. In the second spacer region 23 and the second laminate 25, the second dopant can have a dopant profile similar to that of the first dopant in the first spacer region 13 and the first laminate 15. The second dopant includes, for example, zinc (Zn), beryllium (Be), magnesium (Mg), and carbon (C). Alternatively, the second dopant includes, for example, silicon (Si), sulfur (S), and tellurium (Te).

In the second spacer region 23, the first portion 23a has a second dopant concentration larger than or equal to, for example, 1×10¹⁷ cm⁻³, and the second portion 23b has a second dopant concentration smaller than, for example, 1×10¹⁷ cm⁻³. Specifically, the dopant concentration in the second spacer region 23, which is represented by the dopant profile, monotonously decreases from a value at the boundary between the first laminate 15 and the second spacer region 23, in the first portion 23a of the second spacer region 23, and sometimes reaches a dopant concentration smaller than 1×10¹⁷ cm⁻³ in the second portion 23b. The dopant profile in the second spacer region 23 having a substantially single composition has, like the dopant profile PD, a monotonously decreasing portion in the second spacer region 23.

Further, in a path from the second laminate 25 to the second portion 23b of the second spacer region 23, the first portion 23a (the first portion 23a having a dopant concentration larger than 1×10¹⁶ cm⁻³) is provided to carriers flowing from the second laminate 25 to the active layer 17. In the vertical cavity surface emitting laser 11 including the thick laminated bodies (15 and 25) that implement the two distributed Bragg reflectors, the second spacer region 23, which includes the first portion 23a and the second portion 23b that are located between the active layer 17 and an upper contact layer 29, can prevent that the dopant distribution in the vicinity of the active layer 17 restricts the high-speed modulation performance.

In the present example, the distance between the second laminate 25 and the active layer 17 is larger than or equal to 5 nanometers in the direction of the first axis Ax1, and the second spacer region 23 fills in a gap between the second laminate 25 and the active layer 17. The lower limit value thereof is for causing the containment of light having arisen in the active layer into the vicinity of the active layer to be sufficiently large. Further, the distance between the second laminate 25 and the active layer 17 is smaller than or equal to 20 nanometers in the direction of the first axis Ax1, and the second spacer region 23 fills in a gap between the second laminate 25 and the active layer 17. The upper limit value thereof is for sufficiently ensuring the electrical conductivity between the second laminate 25 and the active layer 17, and achieving the high-speed modulation performance.

Further, the vertical cavity surface emitting laser 11 further includes the upper contact layer 29. In the present example, the second laminate 25 mounts the upper contact layer 29. The vertical cavity surface emitting laser 11 further includes a current confinement structure 31. In the present example, the second laminate 25 includes in its inside the current confinement structure 31. Specifically, the current confinement structure 31 includes a current aperture region 31a and a current block region 31b. The current block region 31b surrounds the current aperture region 31a, and carriers flowing through the second laminate 25 flow through the current aperture region 31a without flowing through the current block region 31b. The current aperture region 31a includes II-V compound semiconductors, and the current block region 31b includes oxides of constituent elements of the III-V compound semiconductors.

In the present example, the second portion 13b of the first spacer region 13 is provided in such a way as to reach the first portion 13a from an outermost well layer 17a of the active layer 17. Further, the second portion 23b of the second spacer region 23 is provided in such a way as to reach the first portion 23a from the outermost well layer 17a of the active layer 17.

The active layer 17 is provided between the first laminate 15 and the second laminate 25, and an optical resonator of the vertical cavity surface emitting laser 11 includes the first laminate 15 and the second laminate 25.

The vertical cavity surface emitting laser 11 can further include a substrate 27. The first spacer region 13 and the first laminate 15 are provided between the substrate 27 and the active layer 17. The substrate 27 contains, for example, GaAs, GaP, GaSb, InP, InAs, AlSb, or AlAs.

The vertical cavity surface emitting laser 11 has a post structure 33. The post structure 33 is provided above a first region 27a of the substrate 27, and the lower laminate portion 15d of the first laminate 15 and the lower portion of the lower contact layer 21 are provided on a second region 27b of the substrate 27. The second region 27b surrounds the first region 27a. The post structure 33 has an upper face 33a and a side face 33b. In the present example, the post structure 33 includes the upper contact layer 29, the second laminate 25, the second spacer region 23, the active layer 17, the first spacer region 13, the upper laminate portion 15u of the first laminate 15, and the upper portion of the lower contact layer 21.

The vertical cavity surface emitting laser 11 includes an insulating protection film 35, an upper electrode 37, and a lower electrode 39. The insulating protection film 35 covers the upper face 33a and the side face 33b of the post structure 33, and the surface of the lower portion of the lower contact layer 21. The upper electrode 37 and the lower electrode 39 are respectively coupled to the upper contact layer 29 and the lower contact layer 21. The insulating protection film 35 has a first opening 35a located at the upper face 33a of the post structure 33, and a second opening 35b located above the second region 27b of the substrate 27. The upper electrode 37 and the lower electrode 39 respectively are in contact with the upper contact layer 29 and the lower contact layer 21 via the first opening 35a and the second opening 35b.

An example of the vertical cavity surface emitting laser 11.

Substrate 27: (100) plane GaAs semiconductor substrate.

Lower contact layer 21: n-type GaAs, and thickness is 100 to 800 rm.

First laminate 15.

Upper laminate portion 15u: n-type GaAs/n-type AlGaAs superlattice.

n-type GaAs: thickness is 40 to 90 nm.

n-type AlGaAs: thickness is 40 to 90 nm.

Thickness of superlattice structure: 400 to 5400 nm.

The number of layers: 5 to 30.

Lower laminate portion 15d: i-type GaAs/i-type AlGaAs superlattice.

i-type GaAs: thickness is 40 to 90 nm.

i-type AlGaAs: thickness is 40 to 90 nm.

Thickness of superlattice structure: 1600 to 5200 nm.

The number of layers: 20 to 40.

First spacer region 13: AlGaAs, and thickness is 5 to 20 nm.

Active layer 17: GaAs/AlGaAs quantum well structure, InGaAs/AlGaAs quantum well structure, or AlInGaAs/AlGaAs quantum well structure.

Thickness of quantum well structure: 10 to 80 nm.

Second spacer region 23: AlGaAs, and thickness is 5 to 20 nm.

Second laminate 25: p-type GaAs/p-type AlGaAs superlattice.

The number of layers: 5 to 30.

p-type GaAs: thickness is 40 to 90 nm.

p-type AlGaAs: thickness is 40 to 90 nm.

Thickness of superlattice structure: 400 to 5400 nm.

Current confinement structure 31.

Current aperture region 31a: AlGaAs, thickness is 10 to 50 nm, and Al composition is 0.9 to 0.96.

Current block region 31b: oxides of group II constituent elements, specifically, aluminum oxide and gallium oxide.

Upper contact layer 29: p-type GaAs or p-type AlGaAs, and thickness is 100 to 300 nm.

Insulating protection film 35: silicon-based inorganic insulating film, for example, silicon oxide, or silicon oxynitride film.

Upper electrode 37: AuGeNi.

Lower electrode 39: AuGeNi.

In FIG. 1, a sign “CAL” denotes a level of 0.35 for the aluminum composition of the first spacer region 13. Further, a sign “C1” denotes a dopant level of, for example, 1×10¹⁷ cm⁻³. In the first spacer region 13 having a substantially single composition, the dopant profile PD has a monotonously decreasing portion in the first spacer region 13. Specifically, for example, in the first portion 13a of the first spacer region 13, the dopant concentration, which is represented by the dopant profile PD, monotonously decreases from a value at the boundary between the first laminate 15 and the first spacer region 13, and sometimes reaches a dopant concentration smaller than 1×10¹⁷ cm⁻³ in the second portion 13b.

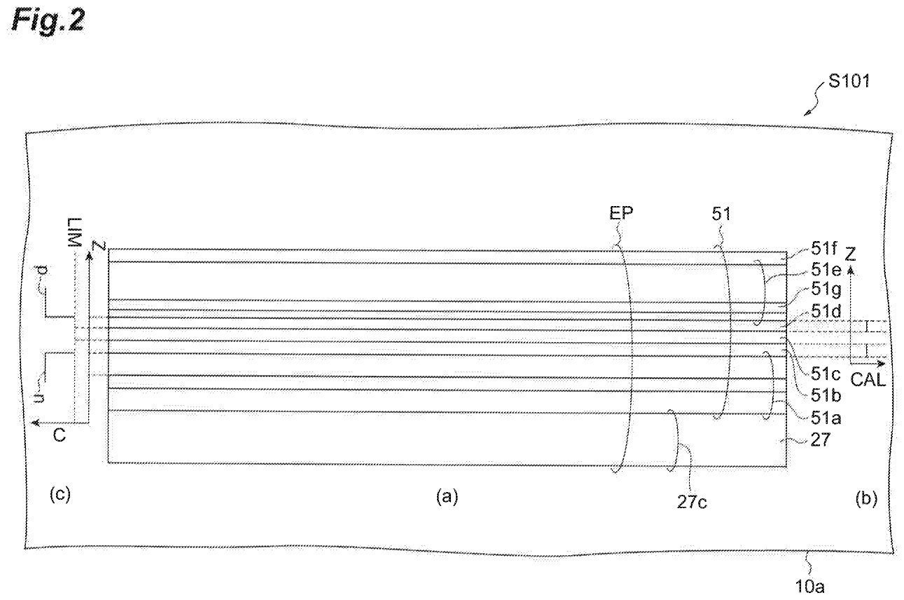

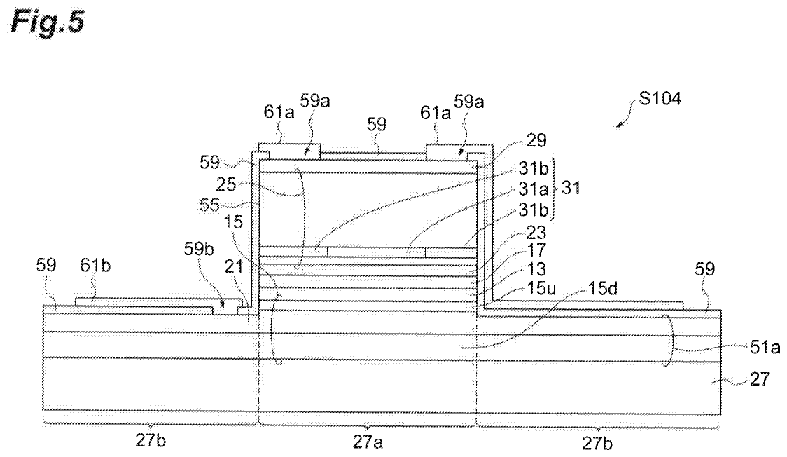

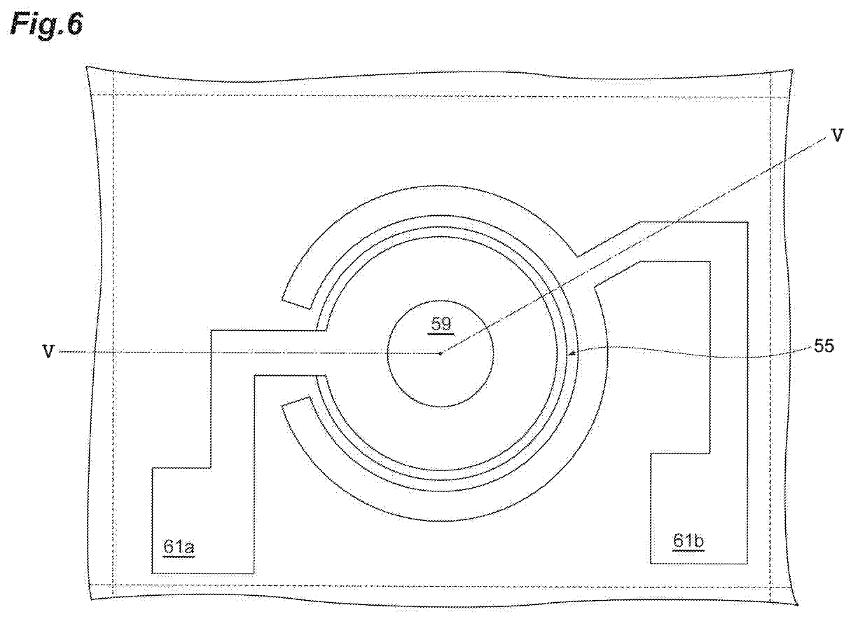

FIGS. 2 to 6 are views schematically illustrating main steps in a method for producing a vertical cavity surface emitting laser, according to the present embodiment. Each of FIGS. 2 to 5 illustrates the area of one element section. FIG. 5 illustrates a cross section taken along the line V-V illustrated in FIG. 6. FIGS. 2 to 5 schematically illustrate steps at the cross-section line illustrated in FIG. 6. A method for producing the vertical cavity surface emitting laser according to the present embodiment will be described with reference to FIGS. 2 to 6. In the following description, in order to facilitate understanding, the reference signs illustrated in FIG. 1 will be used.

The substrate 27 is prepared for a crystal growth. The prepared substrate 27 is disposed in a growth furnace 10a. As illustrated in a portion (a) of FIG. 2, in step S101, a semiconductor laminate 51 is grown on the substrate 27. The semiconductor laminate 51 is grown on a main face 27c of the substrate 27. This growth is performed by, for example, metal organic vapor phase epitaxy and/or molecular beam epitaxy.

Specifically, the semiconductor laminate 51 includes a first semiconductor laminate 51a for the first distributed Bragg reflector; a first semiconductor layer 51b for the first spacer region; a third semiconductor laminate 51c for the active layer; a second semiconductor layer 51d for the second spacer region; a second semiconductor laminate 51e for the second distributed Bragg reflector; and a third semiconductor layer 51f for the upper contact layer 29. Through the crystal growth, the first semiconductor laminate 51a, the first semiconductor layer 51b, the third semiconductor laminate 51c, the second semiconductor layer 51d, the second semiconductor laminate 51e, and the third semiconductor layer 51f are sequentially grown on the main face 27c of the substrate 27. The third semiconductor laminate 51c for the active layer is grown at a temperature of 600 degrees Celsius, and the first semiconductor laminate 51a for the first distributed Bragg reflector, the first semiconductor layer 51b for the first spacer region, the second semiconductor layer 51d for the second spacer region, the second semiconductor laminate 51e for the second distributed Bragg reflector, and the third semiconductor layer 51f for the contact layer are grown at a temperature of 700 degrees Celsius.

The first semiconductor laminate 51a includes semiconductor layers for the lower laminate portion 15d of the first laminate 15, the lower contact layer 21, and the upper laminate portion 15u of the first laminate 15, and the second semiconductor laminate 51e includes a semiconductor layer 51g for the second laminate 25 and the current confinement structure. Semiconductor layers for the lower contact layer 21 and the upper laminate portion 15u of the first laminate 15 are grown while being supplied with, for example, the n-type dopant. Semiconductor layers for the second laminate 25 and the upper contact layer 29 are grown while being supplied with, for example, the p-type dopant. The lower laminate portion 15d of the first laminate 15, the first semiconductor layer 51b, the third semiconductor laminate 51c for the active layer, and the second semiconductor layer 51d are grown as undoped semiconductors without being supplied with the n-type dopant and the p-type dopant.

In an epitaxial substrate EP, the first semiconductor layer 51b for the first spacer region and the second semiconductor layer 51d for the second spacer region have an aluminum profile, such as illustrated in a portion (b) of FIG. 2.

The epitaxial substrate EP has p-type and n-type dopant profiles, such as illustrated in a portion (c) of FIG. 2. The first semiconductor layer 51b and the second semiconductor layer 51d for the spacer regions contain dopant having been supplied through thermal diffusion. However, the third semiconductor laminate 51c for the active layer is substantially kept undoped. Through this step, the first portion 13a and the second portion 13b in the first spacer region 13 are formed. In a necessary case, in order to obtain desired electric characteristics, a heat treatment with no epitaxial growth can be performed (for example, at 600 degrees Celsius for a treatment time of 90 minutes or 105 minutes).

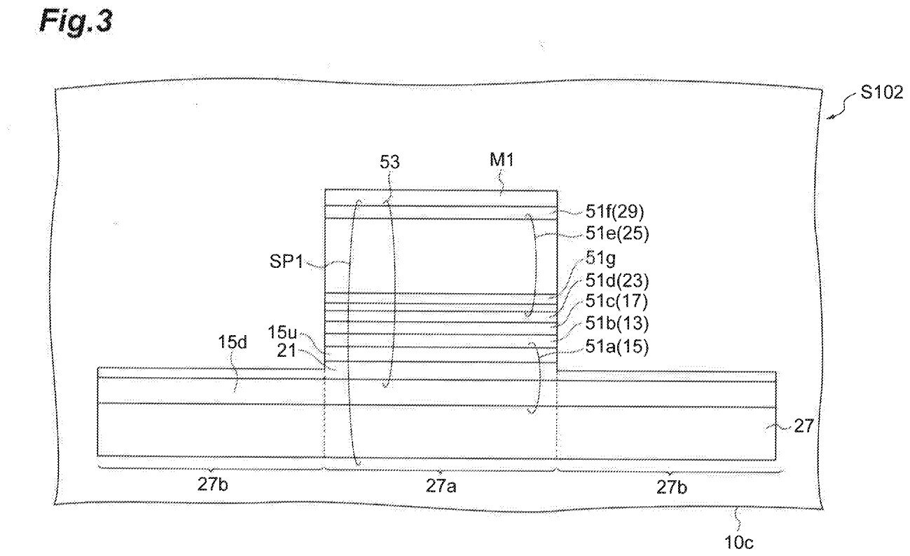

Through the process of the epitaxial substrate EP, a substrate product having a semiconductor post is formed. As illustrated in FIG. 3, in step S102, a mask M1 is formed on the modified epitaxial substrate EP. The mask M1 is produced by, for example, applying photolithography and etching on a silicon-based inorganic insulating film. The mask M1 has a pattern for defining the post of the vertical cavity surface emitting laser 11.

After the mask M1 has been formed, the epitaxial substrate EP is disposed in an etching apparatus 10c. The semiconductor laminate 51 is processed by etching, using the mask M1, and a first substrate product SP1 having a semiconductor post 53 is formed. The semiconductor post 53 of the first substrate product SP1 has a lower end located inside a semiconductor layer for the lower contact layer 21. The first semiconductor laminate 51a for the upper laminate portion 15u of the first laminate 15 is etched and is formed inside the semiconductor post 53, while the first semiconductor laminate 51a for the lower laminate portion 15d of the first laminate 15 is not etched. The semiconductor post 53 is provided above the first region 27a of the substrate 27, and the first semiconductor laminate 51a for the lower laminate portion 15d of the first laminate 15 and the lower portion of the lower contact layer 21 are formed on the second region 27b of the substrate 27.

The etching step can use dry etching and/or wet etching.

After the etching, the mask M1 is removed. The semiconductor post 53 includes a portion of the etched first semiconductor laminate 51a, the etched first semiconductor layer 51b, the etched third semiconductor laminate 51c, the etched second semiconductor layer 51d, the etched second semiconductor laminate 51e, and the etched third semiconductor layer 51f. The central portion of the semiconductor post 53 has substantially the same layer structure as the semiconductors inside the post structure 33 of the vertical cavity surface emitting laser 11 except for the semiconductor layer 51g for the current confinement structure. In the following description, in possible cases, in order to facilitate understanding, the reference signs used in FIG. 1 will be used. Specifically, the semiconductor post 53 includes the upper portion of the lower contact layer 21, the upper laminate portion 15u of the first laminate 15, the first spacer region 13, the active layer 17, the second spacer region 23, the second laminate 25, and the upper contact layer 29. The second laminate 25 includes the semiconductor layer 51g for the current confinement structure.

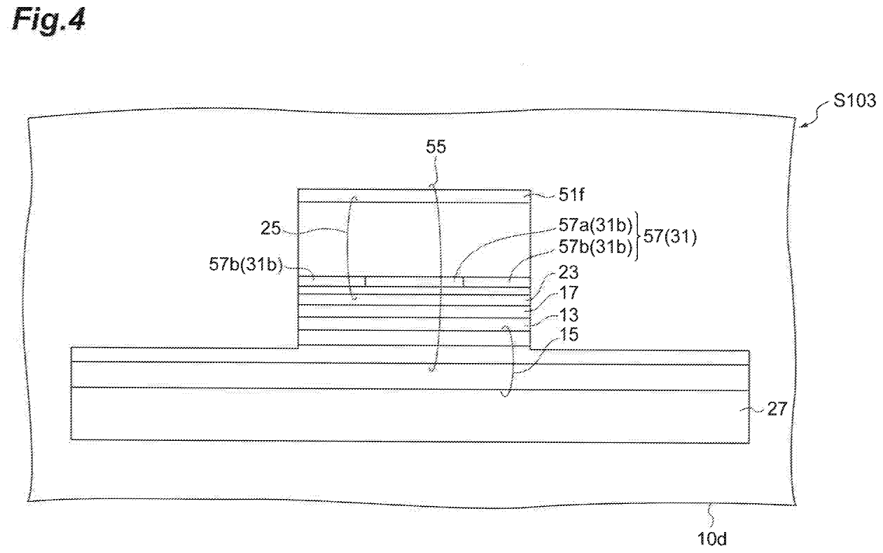

After the mask M1 has been removed, a current confinement structure is formed in the semiconductor post 53 of the first substrate product SP1. As illustrated in FIG. 4, in step S103, the first substrate product SP1 is disposed in an oxidation furnace 10d, and an oxidation atmosphere is formed in the oxidation furnace 10d. A second substrate product SP2 is formed by exposing the semiconductor post 53 to the oxidation atmosphere. The second substrate product SP2 includes a post 55, and the post 55 includes a current confinement structure 57 (31). In the present example, the oxidation atmosphere includes high-temperature steam (for example, 400 degrees Celsius). In the inside of the high-temperature steam, a semiconductor layer containing Al in its constituent elements is gradually oxidized in accordance with its Al composition from the side face of the semiconductor post 53, and in particular, the semiconductor layer 51g having a high Al composition, specifically, AlGaAs (its Al composition being 0.9 to 0.96, its thickness being 10 to 50 nm), is most highly likely to be oxidized among those of the semiconductor post. The current confinement structure 57 (31) includes a current aperture 57a (31a) inside the post 55 and a current block 57b (31b) located outside the inner portion of the post 55. The current block 57b extends along the side face of the post 55, and surrounds the current aperture 57a (31a). The current aperture 57a (31a) consists of an original semiconductor, specifically, AlGaAs (its Al composition being 0.9 to 0.96), and the current block 57b consists of oxides of original semiconductors, specifically, an Al oxide and a Ga oxide. After the current confinement structure 57 (31) has been formed, the second substrate product SP2 is taken out from the oxidation furnace 10d.

The post 55 includes the upper portion of the lower contact layer 21, the upper laminate portion 15u of the first laminate 15, the first spacer region 13, the active layer 17, the second spacer region 23, the second laminate 25, and the upper contact layer 29. The second laminate 25 includes the current confinement structure 31 (57). The dopant concentrations in the first portion 13a and the second portion 13b of the first spacer region 13 keep profiles having been formed by the epitaxial growth.

After the current confinement structure 31 has been formed, an electrode and a passivation film are formed on the second substrate product SP2. As illustrated in FIGS. 5 and 6, in step S104, an insulating film for a passivation film 59 is formed, by vapor phase epitaxy, on the upper face and the side face of the post 55 above the first region 27a of the substrate 27 as well as on the first semiconductor laminate 51a and the lower portion of the lower contact layer 21 on the second region 27b of the substrate 27. The passivation film 59 can contain, for example, SiN. The passivation film 59 has a first opening 59a located at the upper face of the post 55 above the first region 27a, and a second opening 59b located on the upper face of the first semiconductor laminate 51a and the lower portion of the lower contact layer 21 on the second region 27b.

After the passivation film 59 has been formed, a first electrode 61a and a second electrode 61b are formed by photolithography and vapor phase epitaxy. The first electrode 61a and the second electrode 61b respectively are in contact with the upper contact layer 29 and the lower contact layer 21 through the first opening 59a and the second opening 59b of the passivation film 59.

A product having been produced through the steps illustrated in FIGS. 2 to 6 is divided by dicing, and semiconductor chips for the vertical cavity surface emitting laser 11 are obtained.

According to the vertical cavity surface emitting laser 11 by the above production method, the first spacer region 13 provided between the active layer 17 and the first laminate 15 includes the first portion 13a and the second portion 13b. In the first spacer region 13, the first portion 13a is provided in such a way as to reach the second portion 13b from the first laminate 15, and the second portion 13b is provided in such a way as to reach the first portion 13a from the active layer 17. The concentration of the first dopant of the first portion 13a is larger than or equal to 1×10¹⁷ cm⁻³, and the second portion 13b has a concentration smaller than 1×10⁷ cm⁻³ if the first dopant exists. According to the first spacer region 13 including the second portion 13b located between the active layer 17 and the first portion 13a, it is blocked by the diffusion during the production that the dopant reaches the active layer 17 from the first laminate 15. As a result, the dopant in the active layer 17 can be made very low, for example, smaller than a detection lower limit. With the low dopant concentration of the second portion 13b, any generation of a non-radiative recombination center due to the diffused dopant does not substantially occur in the active layer 17. Further, the first portion 13a (the first portion 13a having a high dopant concentration larger than the second portion 13b) in a path from the first laminate 15 to the second portion 13b of the first spacer region 13 can be provided to carriers flowing from the first laminate 15 to the active layer 17.

### EXAMPLE

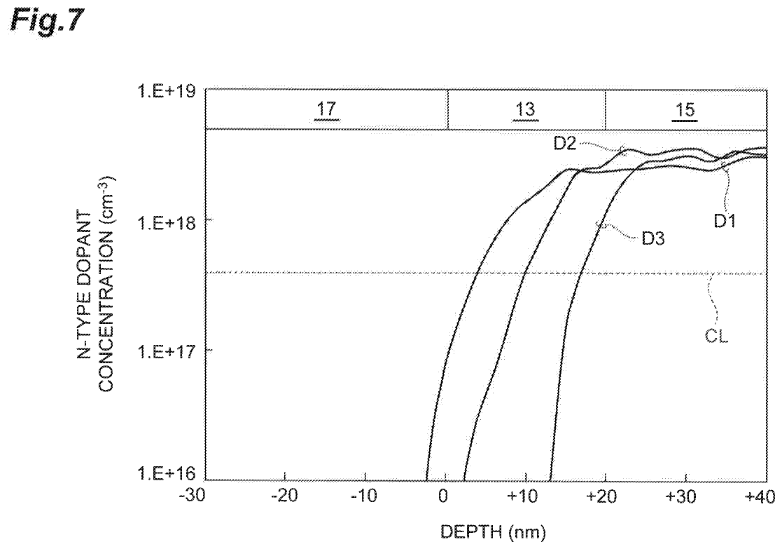

FIG. 7 illustrates an n-type dopant profile in the first laminate 15, the first spacer region 13, and the active layer 17 in a surface emitting laser for optical communication. The abscissa indicates a coordinate on the direction of the first axis Ax1, and the ordinate indicates an n-type (silicon) dopant concentration. In FIG. 7, a notation of the dopant concentration, for example, “1. E+18”, represents 1×10¹⁸. Devices D1, D2, and D3 are vertical resonant type surface emitting lasers that were produced using epitaxial substrates having epitaxial structures in which others except the aluminum compositions of the spacer regions are the same. The thickness of the first spacer region 13 is 20 nm, and the n-type dopant concentration of the first laminate 15 is larger than or equal to 1×10¹ cm⁻³. Further, the devices D1, D2, and D3 have n-type dopant profiles illustrated in FIG. 7.

Specifically, for the n-type dopant from the first laminate 15, the aluminum composition of AlGaAs for the first spacer region 13 enables the reduction of the difference between a design-based n-type dopant profile that is defined by a supply sequence for n-type dopant gas at the time of an epitaxial growth, and an actual n-type dopant profile. Specifically, a large aluminum composition works so as to suppress the diffusion of the n-type dopant.

In vertical cavity surface emitting lasers having thicknesses (5 to 15 nm) of the first spacer region 13 and aluminum compositions (0.30 to 0.40), constant current flowed at a high temperature (for example, 100 degrees Celsius); emission intensities were measured; and variations thereof were measured.

Thickness of AlGaAs, Aluminum Composition, and Achieved Level.

15 nanometers, 030, and 1st level was achieved (an Al composition larger than or equal to 0.30 and a spacer-region thickness larger than or equal to 15 nm).

15 nanometers, 0.35, and 2nd level was achieved (an Al composition larger than or equal to 035 and a spacer-region thickness larger than or equal to 15 nm).

15 nanometers, 0.40, and 2nd level was achieved (an Al composition larger than or equal to 0.4 and a spacer-region thickness larger than or equal to 15 nm).

10 nanometers, 0.30, and 1st level was not achieved.

10 nanometers, 0.35, and 2nd level was achieved (an Al composition larger than or equal to 0.35 and a spacer-region thickness larger than or equal to 10 nm).

10 nanometers, 0.40, and 2nd level was achieved (an Al composition larger than or equal to 0.4 and a spacer-region thickness larger than or equal to 10 nm).

5 nanometers, 0.30, and 1st level was not achieved.

5 nanometers, 0.35, and 1st level was achieved (an Al composition larger than or equal to 0.35 and a spacer-region thickness larger than or equal to 5 nm).

5 nanometers, 0.40, and 1st level was achieved (an Al composition larger than or equal to 0.4 and a spacer-region thickness larger than or equal to 5 nm).

For periods of time taken for the emission intensities of tested devices to decrease to a predetermined level, the period of time in the 2nd level was longer than the period of time in the 1st level.

In the present example, the distance between the first laminate 15 and the active layer 17 is 5, 10, or 15 nanometers in the direction of the first axis Ax1, and the first spacer region 13 fills in a gap between the first laminate 15 and the active layer 17. When the distance is too small, during the production, the dopant diffuses and reaches the active layer. The distance between the first laminate 15 and the active layer 17 is smaller than or equal to 20 nanometers in the direction of the first axis Ax1, and the first spacer region 13 fills in a gap between the first laminate 15 and the active layer 17. When the distance is too large, the electrical conductivity between the lower contact layer and the active layer is decreased (the resistance is increased).

According to experiments by the inventor, in a spacer region containing p-type (zinc (Zn), beryllium (Be), magnesium (Mg), and carbon (C)) dopant, findings similar to those for the first spacer region 13 can be also obtained.

According to the present embodiment, a vertical cavity surface emitting laser and a method for producing a device therefor that make it possible to reduce the variation over time in emission characteristics, and decreasing the rise of series resistance of the device can be provided.

The principles of the present invention have been illustrated and described in the preferred embodiment, and it will be recognized by those skilled in the art that the present invention can be changed in its arrangement and details without departing from such principles. The present invention is not limited to the specific configurations having been disclosed in the present embodiment. Accordingly, we claim rights in all modifications and changes that are derived from the scope of the appended claims and the scope of the spirit thereof.

What is claimed is:

1. A vertical cavity surface emitting laser comprising:
an active layer having a quantum well structure including a well layer and a barrier layer,
a first laminate for a first distributed Bragg reflector; and
a first spacer region provided between the active layer and the first laminate, wherein
the barrier layer includes a first compound semiconductor containing aluminum as a group m constituent element,
the first spacer region includes a second compound semiconductor having a larger aluminum composition than the first compound semiconductor,
the first spacer region includes a first portion and a second portion,
the first laminate, the first portion of the first spacer region, the second portion of the first spacer region, and the active layer are arranged along a direction of a first axis,
the first portion of the first spacer region and the first laminate contain first dopant,
the first portion of the first spacer region is provided from the first laminate to the second portion of the first spacer region,
the second portion of the first spacer region is provided from the active layer to the first portion of the first spacer region,
a concentration of the first dopant in the first laminate is larger than a concentration of the first dopant in the first portion of the first spacer region, and
the concentration of the first dopant in the first portion of the first spacer region is larger than a concentration of the first dopant in the second portion of the first spacer region.

2. The vertical cavity surface emitting laser according to claim 1, wherein
the second compound semiconductor has an aluminum composition larger than or equal to 0.35,
the first laminate contains n-type dopant larger than or equal to 1×10¹⁸ cm³, and
a distance between the active layer and the first laminate is larger than or equal to 10 nanometers in the direction of the first axis.

3. The vertical cavity surface emitting laser according to claim 1, wherein
the concentration of the first dopant in the first portion of the first spacer region is larger than or equal to 1×10¹⁷ cm⁻³, and
the concentration of the first dopant in the second portion of the first spacer region is smaller than 1×10¹⁷ cm⁻³.

4. The vertical cavity surface emitting laser according to claim 1, wherein the concentration of the first dopant in the active layer is smaller than 1×10¹⁶ cm⁻³, and the quantum well structure contains Al_{X}Ga_{1-X}As/In_{1-Y}Ga_{Y}As, here 0.05≤Y≤0.5 being satisfied.

5. The vertical cavity surface emitting laser according to claim 1, wherein the concentration of the first dopant in the active layer is smaller than 1×10¹⁶ cm⁻³, and the quantum well structure contains Al_{X}Ga_{1-X}As/In_{U}Al_{V}Ga_{1-U-V}As, here 0.05≤U≤0.5 and 0<V≤0.2 being satisfied.

6. The vertical cavity surface emitting laser according to claim 1, further comprising:
a substrate;
a second laminate for a second distributed Bragg reflector, and
a second spacer region provided between the active layer and the second laminate, wherein
the first spacer region and the first laminate are provided between the substrate and the active layer,
the active layer is provided between the first laminate and the second laminate, and
the second laminate, a first portion of the second spacer region, a second portion of the second spacer region, and the active layer are arranged along the direction of the first axis.
